(19) United States
(12) Patent Application Publication
(10) Pub. No.: US 2026/0141135 A1
(43) Pub. Date: May 21, 2026

(54) OPTIMIZATION SYSTEM AND METHOD

(71) Applicant: Detechtion USA Inc., Houston, TX (US)

(72) Inventors: Ruchita Robert Rozario, Toronto (CA); Brandon Samuel Ambrose, Valleyview (CA); Nicholas Rolland Lefebvre, St. Albert (CA)

(21) Appl. No.: 19/054,103

(22) Filed: Feb. 14, 2025

Related U.S. Application Data
(60) Provisional application No. 63/721,281, filed on Nov. 15, 2024.

(51) Int. Cl. G06F 30/18; G08B 21/18

(52) U.S. Cl. CPC G06F 30/18; G08B 21/18

(57) ABSTRACT

A system and method of optimizing. The system and method comprising a prioritization model. The prioritization model comprising a time delta function. The time delta function generates a Fibonacci score for each of a plurality of action items. The prioritization model further comprising a distance optimizer. The distance optimizer determines a best score for each of the plurality of action items. The best score is based on a distance to travel. The prioritization model further comprising an alarm indicator. The alarm indicator generates an alarm indicator input for the prioritization model. The prioritization model generates a prioritized list of the plurality of action items based on the Fibonacci score, the best score, and the alarm indicator input.

### CROSS-REFERENCE TO RELATED APPLICATIONS

This application claims the benefit of co-pending U.S. Provisional Patent Application No. 63/721,281, filed November 15, 2024, the entire contents of which are incorporated by reference.

### FIELD OF INVENTION

The present application relates to a system and method of production optimization of oilfield operations such as for consumption trucking optimization and operator optimization with alarming using Fibonacci prioritization, K-means clustering, and predictive models within an optimization framework.

### BACKGROUND

Much of the data used for optimization of operations is often scattered, unstructured, and/or irrelevant. Existing optimization models are often missing the tools and systems to process, analyze, and derive actionable insights. The existing models are often outdated and are not equipped to handle modern operational challenges.

The optimization model described herein uses a Fibonacci prioritization, K-means clustering, and predictive models within an optimization framework. The inclusion of a validated case study adds practical insights, while the model’s contribution to reducing GHG emissions through optimized operations offers valuable, additive information for practicing engineers focused on sustainability and efficiency.

### SUMMARY

A system of optimizing comprising a prioritization model. The prioritization model comprising a time delta function. The time delta function generates a Fibonacci score for each of a plurality of action items. The prioritization model further comprising a distance optimizer. The distance optimizer determines a best score for each of the plurality of action items. The best score is based on a distance to travel. The prioritization model further comprising an alarm indicator. The alarm indicator generates an alarm indicator input for the prioritization model. The prioritization model generates a prioritized list of the plurality of action items based on the Fibonacci score, the best score, and the alarm indicator input.

In some aspects, the time delta function uses a pigging event, an inspection schedule and a machine schedule, a task, and a non-scheduled event to determine the Fibonacci score.

In some aspects, the pigging event is based on a pigging frequency and a number of days the pigging event is overdue.

In some aspects, the inspection schedule and the machine schedule is based on a pigging frequency and a number of days the pigging event is overdue.

In some aspects, the task is based on a difference between a current date and a creation date.

In some aspects, the non-scheduled event includes a tank reading or a pump reading.

In some aspects, the Fibonacci score is determined by a priority level of each of the plurality of action items.

In some aspects, the alarm indicator input is based on at least one of a well production alarm, a weather-based alarm, and an internally generated alarm.

In some aspects, the well production alarm is a percentage of decrease commodity pricing and percentage of ownership.

In some aspects, the weather-based alarm is either one of an under-injection or an over-injection based on a recommended rate.

In some aspects, the internally generated alarm is either one of a visitation alarm or a pig receiver full alarm.

A method of optimizing having a prioritization model. The prioritization model comprising an alarm indicator. The alarm indicator generates an alarm indicator input for the prioritization model. The method further receiving data and labelling the received data with a Fibonacci score for each of a plurality of action items. The Fibonacci score is generated by a time delta function. The method further using a heuristic data model to determine a best score for each of the plurality of action items. The best score based on a distance to travel. The method further testing the prioritization model for a duration of time. The method further performing a continuous improvement cycle to reinforce an efficiency of the prioritization model. The method generating a prioritized list of the plurality of action items based on the Fibonacci score, the best score, and the alarm indicator input.

In some aspects, the time delta function uses a pigging event, an inspection schedule and a machine schedule, a task, and a non-scheduled event to determine the Fibonacci score.

In some aspects, the pigging event is based on a pigging frequency and a number of days the pigging event is overdue.

In some aspects, the inspection schedule and the machine schedule are based on a pigging frequency and a number of days the pigging event is overdue.

In some aspects, the task is based on a difference between a current date and a creation date.

In some aspects, the non-scheduled event includes a tank reading or a pump reading.

In some aspects, the Fibonacci score is determined by a priority level of each of the plurality of action items.

In some aspects, the alarm indicator input is based on at least one of a well production alarm, a weather-based alarm, and an internally generated alarm.

In some aspects, the duration of time is 90 days.

A method of optimizing comprising a prioritization model. The prioritization model comprising an alarm indicator. The alarm indicator generates an alarm indicator input for the prioritization model. The alarm indicator input is based on at least one of a well production alarm, a weather-based alarm, and an internally generated alarm. The alarm indicator comprising an alarm review, wherein an at least one operator reviews an alarm received from at least one of the well production alarm, the weather-based alarm, and the internally generated alarm. The alarm indicator further comprising an investigation to manage the received at least one alarm. The alarm indicator further comprising a data entry, wherein each of the at least one operator inputs a start and end location, a work duration, and a constraint. The alarm indicator further comprising a plan generator. The plan generator generates an optimized action item list and an optimized route. The alarm indicator further comprising a manual review process by the at least one operator. The at least one operator performs the manual review process and updates the generated optimized action item list and the optimized route. The alarm indicator further comprising executing the updated generated optimized action item list and the optimized route.

In some aspects, the optimized action item list and the optimized route are based on a travel time, a priority level for each of the plurality of action items, and an urgency level.

### BRIEF DESCRIPTION OF THE DRAWINGS

FIG. 1 is a system of an optimization model;

FIG. 2 is an embodiment of the system architecture of the optimization model of FIG. 1;

FIG. 3 is a flow chart of key phases of a method of the optimization model of FIG. 2;

FIG. 4 is a flow chart of a method of reviewing and optimizing alarms of the optimization model of FIG. 2;

FIG. 5 is a graph of the priority and warning levels of the optimization model of FIG. 2;

FIG. 6 is a graph of heuristic data modelling of FIG. 3;

FIG. 7 is a graph of clustered data points used in heuristic data modelling of FIG. 3;

FIG. 8 is a graph of the maximized production before and after implementing the optimization model of FIG. 1;

FIG. 9 is a graph of the excess methanol used before and after implementing the optimization model of FIG. 1;

FIG. 10 is a graph of the number of days delinquent for compliant and low risk operations before and after implementing the optimization model of FIG. 1; and

FIG. 11 is a stack architecture of the optimization model of FIG. 1.

### DETAILED DESCRIPTION

The following discussion is presented to enable a person skilled in the art to make and use embodiments of the technology described by the present application. Various modifications to the illustrated embodiments will be readily apparent to those skilled in the art on reading the disclosure, and the generic principles herein can be applied to other embodiments and applications without departing from embodiments of the present application. Thus, embodiments described by the present application are not intended to be limited to embodiments shown but are to be accorded the widest scope consistent with the principles and features disclosed herein. The following detailed description is to be read with reference to the figures, in which like elements in different figures have like reference numerals. The figures, which are not necessarily to scale, depict selected embodiments and are not intended to limit the scope of embodiments of the invention. Skilled artisans will recognize the examples provided herein have many useful alternatives and fall within the scope of embodiments of the technology described herein.

Before any embodiments of the present application are explained in detail, it is to be understood that the technology described is not limited in its application to the details of construction and the arrangement of components set forth in the following description or illustrated in the attached drawings. The technology of the present application is capable of other embodiments and of being practiced or of being carried out in various ways. Also, it is to be understood that the phraseology and terminology used herein are for the purpose of description and should not be regarded as limiting. For example, the use of “including,” “comprising,” or “having” and variations thereof herein is meant to encompass the items listed thereafter and equivalents thereof as well as additional items.

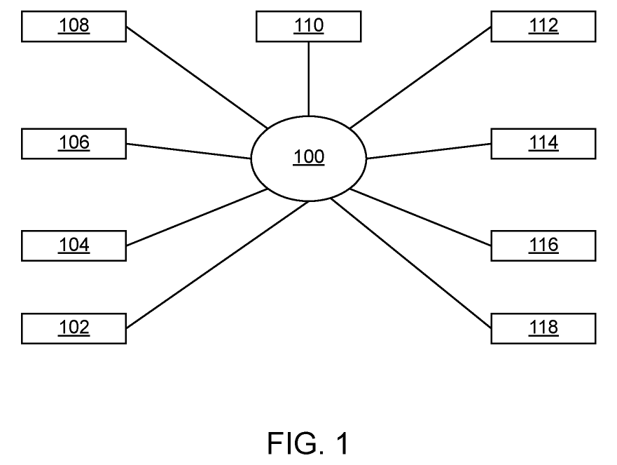

FIG. 1 is an optimization model 100 that may use a software operating on a specially programmed machine or a processor specifically containing instructions and code to perform the functions fully described herein. The optimization model 100 may employ heuristics and metaheuristics algorithms to optimize trucking, routing, and maintenance operations among other things. These heuristics and metaheuristics may include, but are not limited to, Local Search, Simulated Annealing, and Tabu Search. Unlike traditional machine learning algorithms, the optimization techniques of optimization model 100 explore the solution space efficiently to find near-optimal solutions to complex problems.

Optimization model 100 may begin with process and data acquisition 102. Process and data acquisition 102 is a step where data is gathered such as tank and location details from out of an application programming interface (API) endpoint, focusing specifically on the latest tank rates. The data forms the foundation for the initial solution, providing a preliminary blueprint for deeper analysis and refinement. The collected data may be stored to a memory.

Optimization model 100 may further include a heuristic method 104. In some instances, the heuristic methods 104 may include, but are not limited to, greedy algorithms, which make optimal choices at each stage with the aim of finding a global optimum. In some instances, the heuristic methods 104 may include a divide and conquer approach, which breaks down a problem into smaller sub-problems, solve the smaller sub-problems independently, and then combines the results. In some instances, the heuristic methods 104 may include genetic heuristics, which evolve solutions based on simple selection rules. In some instances, the heuristic methods 104 may include a nearest neighbor approach, which is often used in routing problems, where an algorithm chooses the nearest location, such as, for example, the nearest house, city, town, or neighborhood for the next stop. In some instances, the heuristic methods 104 may include a rule-based system, which uses if-then rules in decision-making processes, such as, for example, in knowledge-based systems or game strategies.

In one instance, for example, a heuristic method 104 may include a Fibonacci Score for prioritization of field events. A Fibonacci Score may be a range, for example, a range from Fibonacci(4) which is equal to 3 to Fibonacci(16) which is equal to 987. In another instance, for example, a heuristic method 104 may include K-means clustering to optimize routing, and data-based rules that integrate domain expertise and statistical principles to predict well performance. In one instance, heuristic method 104 may be tested over a period of time, such as, for example, three months, using data simulation with real feedback from the operations team used to fine-tune and improve the heuristic method 104 accuracy. In other instances, the heuristic methods 104 may be tested over a longer or shorter time period, such as, for example, a period of days, weeks, months, or years. Additionally, the heuristic methods 104 may be validated based on the performance in key areas such as maximizing production and reducing operational costs. A heuristic method 104 may include, integrating a routing algorithm to optimized operator routes. In one instance, the heuristic method 104 may determine the shortest possible route that visits every point in a set location one time. In another instance, for example, the heuristic method 104 may use a forecasting technique to study a well’s natural decline to determine and predict when a well will experience a dip in production. Further in other instances, the prediction of when a well will experience a dip in production may trigger an alarm to indicate a need for maintenance of the well. Heuristics methods 104 play a pivotal role in the framework, offering a pragmatic approach to quickly generate viable solutions. The methods set a robust foundation for the optimization journey, enabling rapid production of sufficiently good solutions, especially when navigating vast or ambiguous defined solution spaces.

Optimization model 100 may employ a metaheuristics algorithm 106. In some instances, the metaheuristic algorithms 106 include, but are not limited to, Local Search, Simulated Annealing, and Tabu Search. Metaheuristic algorithms 106 may be where the real depth of the framework is realized. In some instances, metaheuristic algorithms 106 may include Particle Swarm Optimization (PSO), which is inspired by bird flocking and includes optimization of particles, where candidate solutions explore the solution space influence by their neighbors such as, but not limited to, instances involving engineering, robotics and network design. In some instances, metaheuristics 106 may include Ant Colony Optimization (ACO), which is inspired by ant foraging and uses a probabilistic technique for finding optimal paths, especially useful in routing, scheduling, and logistics problems. In some instances, metaheuristic algorithms 106 may include Genetic Algorithms (GA), which is based on evolution and uses selection, crossover, and mutation to evolve solutions over generations and which may be used in instances involving engineering design, finance, and machine learning. In some instances, metaheuristic algorithms 106 may include Bee Algorithm, which is based on bees modeling foraging behavior to find optimal solutions and is particularly popular in dynamic environments such as, but not limited to, network routing and resource allocation. In some instances, metaheuristic algorithms 106 may include Differential Evolution (DE), which is a population-based stochastic method that optimizes problems by combining solutions from multiple sources and is often used in continuous optimization problems, such as, but not limited to, parameter estimation and image processing.

In one instance, for example, metaheuristic algorithms 106 may include a Local Search that methodically evaluates neighboring solutions, fostering incremental improvements. In another instance, for example, metaheuristic algorithms 106 may include a simulated annealing, which introduces a probabilistic component, allowing for occasional steps in suboptimal directions to avoid local minima traps. In yet another instance, for example, metaheuristic algorithms 106 may include a Tabu Search, which enhances the search process by avoiding the repetition of previously explored solutions, pushing the boundaries of exploration to uncover new possibilities. The metaheuristic algorithms 106 may be similar to the heuristic methods 104 described above in order to further refine the efficiency of optimization model 100. In one instance, a metaheuristic algorithm 106 may include a Fibonacci Score for prioritization of field events. A Fibonacci Score may be a range, for example, a range from Fibonacci(4) which is equal to 3 to Fibonacci(16) which is equal to 987. In another instance, a heuristic method 104 may include K-means clustering to optimize routing, and data-based rules that integrate domain expertise and statistical principles to predict well performance. In one instance, metaheuristic algorithm 106 may be tested over a period of time, such as, for example, three months, using data simulation with real feedback from the operations team used to fine-tune and improve the metaheuristic algorithm 106 accuracy. In other instances, the metaheuristic algorithm 106 may be tested over a longer or shorter time period, such as, for example, a period of days, weeks, months, or years. Additionally, the metaheuristic algorithm 106 may be validated based on the performance in key areas such as maximizing production and reducing operational costs. A metaheuristic algorithm 106 may include, integrating a routing algorithm to optimized operator routes. In one instance, the metaheuristic algorithm 106 may determine the shortest possible route that visits every point in a set location one time. In another instance, for example, the metaheuristic algorithm 106 may use a forecasting technique to study a well’s natural decline to determine and predict when a well will experience a dip in production. Further in other instances, the prediction of when a well will experience a dip in production may trigger an alarm to indicate a need for maintenance of the well.

Optimization model 100 may further use handling constraints 108. The framework of handling constraints 108 adeptly handles both explicit and implicit constraints, ensuring that the search remains relevant and focused. In some instances, for example, the constraints 108 may include, but are not limited to, start and end locations, distance limitations, work duration, travel time, fuel type, fuel level limits, priority and urgency of tasks, time to complete each task, and other optional filters. In one instance, for example, the constraints 108 may be a ‘vehicle Capacity’ constraint which checks if the demand is greater than the capacity of the truck. In one instance, for example, the constraints 108 may be a ‘tank Not Ready’ constraint which determines if the demand for the thank is less than the rate, then there is no need to fill the tank. In one instance, for example, the constraints 108 may be a ‘tank Empty’ constraint which never allows the tank to go empty. In one instance, for example, the constraints 108 may be a ‘daysLeftTilEmpty’ constraint which should never be less than eight days, unless a tank is critical. In one instance, for example, the constraints 108 may be a ‘methanolCost’ constraint which rewards higher product movement. The nuanced understanding of the constraints is crucial for steering the search towards feasible and effective solutions.

Optimization model 100 may further include an iterative process 110. The iterative process 110 defines the effectiveness. Each iteration of the iterative process 110 builds upon insights from the previous one, allowing for continuous refinement and convergence toward an optimal solution. Each iteration may be saved to a memory. The memory may contain the date from individual iterations as well as historical data. The iterative process 110 retrieves the data from memory to refine the process and develop an optimal solution. In some instances, the iterative process 110 may retrieve data from individual iterations. In other instances, the iterative process may retrieve historical data. The cycle balances exploring new possibilities and exploiting known good solutions, ensuring a comprehensive and thorough search process.

Optimization model 100 may include integration of reinforcement learning 112. To enhance the optimization model 100 further, reinforcement learning 112 algorithms, such as greedy algorithms. In some instances, reinforcement learning 112 involves an agent learning to make decisions by performing actions and receiving feedback through rewards or penalties. In other instances, the reinforcement learning 112 is performed automatically and may involve retrieving data from individual instances as well as historical data from memory. Specifically, greed algorithms in reinforcement learning 112 helps in making immediate optimal choices, with the model refining the choices based on outcomes to improve long-term performance.

Optimization model 100 may further include customization and flexibility 114. The optimization solution heavily relies on software due to its flexibility compared to other alternatives. Customization and flexibility 114 allows the optimization model 100 to customize and build on the previous results to meet the specifications and scale the product when ready. In some instances, the customization and flexibility 114 may automatically adapt to meet the specifications. In other instances, an agent may force an adaptation to meet specifications. The specifications may be preset or may be adjusted depending on the job constraints. The job constraints may be set specific to the domain problem and the uniqueness of the data. Job constraints may include, for example, emptying tanks within the operator-specified timeframe, creating a schedule that optimizes delivery costs per liter over a selected period, start and end locations, distance limitations, work duration, travel time, fuel type, fuel consumption limits, priority and urgency of tasks, time to complete each task, volume of material to be transferred, and other optional filters. In some instances, the specifications may be the time to complete each task. In one instance, for example, the time to complete a pig schedule may be set to 5 minutes. In another instance, for example, the time to complete a pig receiving may be set to 5 minutes. In another instance, for example, the time to complete an inspection may be set to 5 minutes. In yet another instance, for example, the time to complete a machine schedule may be set to 120 minutes, 2 minutes for a sample, or a number of days for an overhaul. In another instance, for example, the time to complete a pump reading may be set to 2 minutes. In yet another instance, for example, the time to complete a tank reading may be set to 1 minute. In another instance, for example, a visitation alarm or a full receiver alarm may have a time to complete set to zero minutes. However, in another instance, for example, the time to complete a rate change alarm may be set to 4 minutes. In yet another instance, for example, the time to complete a Down Production Alarm may be set to 30 minutes. In yet another instance, for example, the time to complete a voltage alarm may be set to 20 minutes, or may be revised to 5 minutes for a low voltage alarm, or to “ignore” a high voltage alarm. In another instance, for example, the time to complete a plunger alarm may be set to 20 minutes. In another instance, for example, the time to complete a comms alarm may be set to 20 minutes.

Optimization model 100 may integrate data ingestion and model training 116. During data ingestion and model training 116 data is ingested by consuming the application programming interface (API) endpoint. The optimization model 100 is trained, routinely updated, and run by a scheduled task. In some instances, the scheduled tasks may be performed either periodically at a fixed time, at set intervals, or on an as-needed basis. The optimization model 100 prioritizes tasks by identifying, for example, tanks at risk of emptying within the operator-specified timeframe, creating a schedule that optimizes delivery costs per liter over the selected period.

Additionally, optimization model 100 may integrate operator flexibility 118. Operator flexibility 118 may allow an operator or another agent to modify the timeframe. In some instances, the timeframe modification may include or exclude specific tanks or locations in the optimization process. In some instances, the timeframe may span two to three years. In other instances, the timeframe may be longer or shorter. In some instances, the optimization model 100 may configure the solution to be intra-field such as, for example, limiting deliveries within the same field. In other instances, the optimization model 100 may configure the solution to be inter-field such as, for example, allowing deliveries across different fields using the same vehicle. In yet other instances, the optimization model may configure the solution to, for example, tailor the routing to meet a specific operation’s needs.

In one instance, a benefit of optimization model 100 may be to enhance economic efficiency. One way to enhance economic efficiency, for example, may be to minimize fuel and operational cost relative to the volume of material transported, ensuring cost-effective delivery schedules. The example is not meant to be limiting, there may also be other ways to enhance economic efficiency.

In another instance, a benefit of optimization model 100 may be to optimize resource utilization. One way to optimize resource utilization, for example, may be to maximize the utilization of the vehicle fleet, reducing idle times, and improving overall logistical performance. The example is not meant to be limiting, there may also be other ways to optimize resource utilization.

In another instance, a benefit of optimization model 100 may be to improve spatial efficiency. One way to improve spatial efficiency, for example, may be to minimize the distances between delivery locations, thereby reducing travel times, fuel consumption, and vehicle wear and tear. For example, improving spatial efficiency may be performed during heuristic methods 103 and metaheuristic algorithms 106 and further optimized during the iterative process 110 and reinforcement learning 112. The example is not meant to be limiting, there may also be other ways to improve spatial efficiency.

In yet another instance, a benefit of optimization model 100 may be to support environmental sustainability. One way to support environmental sustainability, for example, may be to lower carbon emissions through optimized routing and efficient vehicle usage, aligning with sustainability goals. The example is not meant to be limiting, there may also be other ways to support environmental sustainability.

In another instance, a benefit of optimization model 100 may be to ensure flexible and scalable solutions. One way to ensure flexible and scalable solutions, for example, may be to provide a customizable and scalable framework that can adapt to specific operational needs and grow with the requirements. The flexible and scalable solutions may be adjusted by the constraints 108 and/or adjusting the specifications during customization and flexibility 114. The example is not meant to be limiting, there may also be other ways to ensure flexible and scalable solutions.

The framework of optimization model 100 may leverage advanced computational algorithms to navigate the complexities of solution spaces. By integrating heuristic and metaheuristic techniques, such as heuristic methods 104 and metaheuristics algorithms 106 as described above, and planning for reinforcement learning algorithms, the optimization model 100 not only solves problems but uncovers a spectrum of possibilities, providing the most effective and efficient solutions.

The optimization model 100 may introduce several innovative features designed to enhance operational efficiency and logistical effectiveness such as during the iterative process 110 and reinforcement learning 112. For example, a cost per landed liter analysis may focus on evaluating the economic efficiency of the delivery schedules by analyzing the cost per liter of transported material. Additionally, by calculating and optimizing the cost per liter, the optimization model 100 may ensure that fuel and operational costs are minimized relative to the volume of the material transported. Calculating and optimizing the cost per liter may be a direct measurement of the optimization model’s 100 effectiveness in reducing operational expenses, ensuring cost-effective scheduling and routing decisions. In another example, truck utilization monitoring measures the utilization rate of the vehicle fleet to gauge logistical efficiency. By tracking and optimizing truck utilization, the optimization model 100 may identify inefficiencies such as underused resources or suboptimal scheduling. The high utilization rate may indicate optimal use of vehicles, reducing idle times and improving overall asset usage, thereby enhancing logistical performance. In yet another example, distance minimization between locations may evaluate and optimize the spatial efficiency of delivery routes by minimizing the distances between locations. The optimization model may generate routes that reduce travel times, fuel consumption, and vehicle wear and tear, which, in turn, leads to faster delivery times, lower carbon emissions, and improved efficiency, aligning with both operational and environmental solutions in complex logistical scenarios. Overall, the optimization model 100 may embody innovative features that significantly enhance operational and logistical efficiency. The new results obtained through the practice of these features underscore their impact, demonstrating substantial improvements in cost reduction, resource, utilization, and environmental sustainability. These advancements may highlight the optimization model’s 100 capability to drive effective and efficient solutions in complex logistical scenarios.

In one instance, the optimization model 100 may be used for the selection of liquid, which may include a logistics coordinator that begins by selecting a type of liquid to generate for package delivery. In some instances, the type of liquid may include, but is not limited to, one of Methanol, Scavenger, or Corrosion Inhibitor. Further, the optimization model 100 may generate a recommended package, or packages, based on factors like truck size, tank locations, and the origin depot for picking up the commodity. The optimization model 100 also analyzes the recommended packages. The logistics coordinator may review the recommended package, or packages, evaluating details such as, but not limited to, truck sizes, the list of tanks to be serviced, and the origin depot. Once a package is selected, the coordinator may download the package details and informs the respective trucking company of the order. The logistics coordinator toggles the selected packages as “ordered” within the system.

The operators manage numerous fields and field operations. In one instance, the operators ensure tanks and pumps function correctly and have the proper injection rates and chemical additives. In another instance, the operators ensure timely inspections for health and safety. In another instance, the operators ensure pigs are sent on schedule. The schedule may be periodically at a fixed time, at set intervals, or on an as-needed basis when requested by an operator. In another instance, the operators may address Ad-hoc tasks promptly. In yet another instance, the operators may package locations to minimize travel time. In one instance, the optimization model 100 may determine production issues, such as, for example, a loaded well, malfunctioning plunger, or incorrect valve pressure. In one instance, the optimization model 100 may prioritize production issues over other tasks. For example, in one instance, the optimization model 100 may compare one production issue to another task, determining that a malfunctioning plunger requires immediate attention, while the other task can wait until the malfunctioning plunger is repaired. In another instance, the optimization model 100 may determine that an incorrect valve pressure reading requires greater priority requiring immediate attention, while the other task can wait until the incorrect valve pressure reading is corrected. In yet another instance, the optimization model 100 may determine that a loaded well requires greater priority requiring immediate attention, while another task can wait until the loaded well is corrected. Some additional challenges the operators may face include external data, such as, but not limited to, weather, road bans, site accessibility, and/or contractor availability.

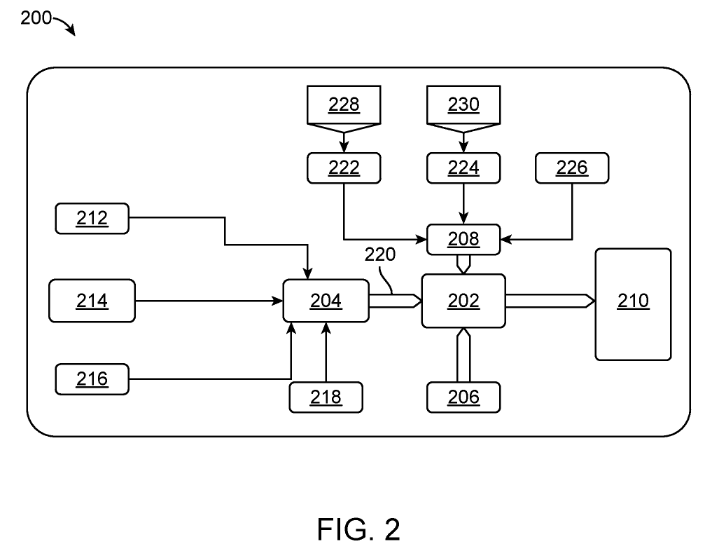

FIG. 2 illustrates a system 200 including a prioritization model 202 which receives inputs from a time delta function 204, a distance optimization 206, and an alarm indicator 208. The prioritization model 202 produces an output of a prioritized list 210. The prioritized list 210 may be a list of action items that need to be completed with a priority level attached. The priority level indicates whether one action item should be completed before another action item. The prioritized list 210 is generated based on at least one of an origin, a distance, a location, a tank, an oil field, a delivery, a reading, a solution, an alarm or warning signal, and a truck.

The time delta function 204 may include, but is not limited to, an input from a pigging event 212, an inspection schedule and a machine schedule 214, at least one task 216, and one or more non-scheduled event(s) 218. The pigging event 212 input may include, for example, a calculation of the impact of the pigging frequency and overdue delays. The inspection schedules and machine schedules 214 input may include, for example, a calculation of the impact of the pigging frequency and overdue delays. The task 216 input may include, for example, the impact of the delta between the current data and the creation date. Additionally, the one or more non-scheduled event(s) 218 input may include, for example, at least one of a tank reading and/or a pump reading. Further, the time delta function 204 may calculate a Fibonacci Score 220 to send to the prioritization model 202. A Fibonacci Score 220 may be a range, for example, a range from Fibonacci(4) which is equal to 3 to Fibonacci(16) which is equal to 987.

Additionally, a distance optimization 206 may determine the best score with the least amount of travel. The distance optimization 206 may determine which action item requires the least amount of distance to travel between each action item. The distance optimization 206 may provide a score for each action item based on the distance of travel between each action item. The action item that has the best score is the action item with the least amount of distance to travel. The determined best score with the least amount of travel is sent to the prioritization model 202. In one instance, the best score may be lowest score. In another instance, the best score, may be the highest score.

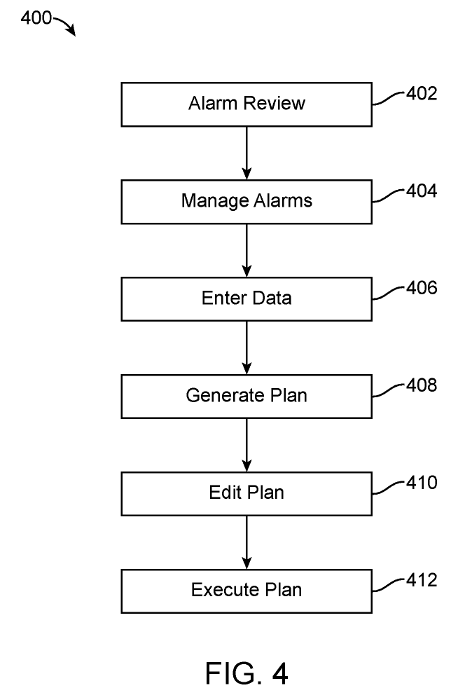

Additionally, the alarm indicator 208 input may include a well production 222, a weather-based alarm 224, and/or an internally generated alarm 226, such as from an equipment parameter or the like. The well production 222 may receive external data 228 such as, but not limited to, production data and commodity prices. The well production 222 may use the external data 228 to calculate the percent decrease of commodity pricing and percent ownership. The percent decrease of commodity pricing may be calculated from the current value and the mean of the last month. Further, the weather-based alarm 224 may receive external data 230 such as, but not limited to, the weather forecast and current weather data. The weather-based alarm 224 may use the external data 230 to calculate an under-injection rate and/or over-injection rate based on a recommended rate. The recommended rate may be an input from the human operator or may be a pre-determined range. Further, the internally generated alarm 226 may include either a determination of the visitation alarm or a determination of a pig receiver full alarm. When the alarm indicator 208 receives an input from any one of either the well production 222, weather-based alarm 224, or the internally generated alarm 226, the alarm indicator 208 sends the received alarm input to the prioritization model 202. The method followed by the alarm indicator 208 is discussed further in FIG. 4.

The prioritization model 202 may determine a priority of each of the action items based on the received inputs from the time delta function 204, the distance optimization 206, and the alarm indicator 208. The prioritization model 202 may generate the prioritized list 210 of action items further based on at least one of an origin, a distance, a location, a tank, an oil field, a delivery, a reading, a solution, an alarm or warning signal, and a truck. In one instance, for example, the prioritization model 202 may determine that a plunger inspection requires attention before a monthly carseal inspection in order to prevent a drop in production. As such, the prioritization model 202 may indicate that the plunger inspection is higher on the prioritization list 210 than the monthly carseal inspection. In another instance, for example, a riser inspection may require attention before a plunger inspection. As such, the prioritization model 202 may indicate that the riser inspection is higher on the prioritization list 210 than the plunger inspection. In yet another instance, the prioritization model 202 may determine that the vehicle needs to visit the refuel station before a preventative maintenance action item can be completed. As such, the prioritization model 202 may indicate that refuelling is higher on the prioritization list 210 than a preventative maintenance action item. Additionally, the prioritization model 202 may flag an action item a “must do.” The prioritization model 202 may ensure the action items that are flagged as “must do” are incorporated in the prioritized list 210. An action item flagged as “must do” may indicate a higher priority over other action items that are not flagged as “must do.” The action items may include, but are not limited to, gas and condensate samples, preventative maintenance, monthly carseal inspection, plunger inspection, ROW inspection, replace broken swadgelok T-fitting, tank inspection, production pig, receive pig, fuel refill, riser inspection, well site inspection, well samples, pull old soiled plunger and replace with spiral plunger, order more replacement components, equipment alarms and warning, etc.

The system 200 may be a data-drivel model designed to enhance oilfield operations by creating efficient action lists and routes for operators. The system 200 may aim to maximize production, reduce operational costs, lower greenhouse gas (GHG) emissions through streamlined travel and field activities, and assist in maintaining a safe and compliant field environment. The scope may include integrating SCADA data with predictive algorithms to foresee and address potential field issues, ensuring operational efficiency while prioritizing safety and compliance.

The system 200 may incorporate several advanced techniques, including Fibonacci Score 220 for prioritization of scoring field events, K-means clustering to optimize routing, and data-based rules that integrate domain expertise and statistical principles to predict well performance. A heuristic approach, integrating a routing algorithm, may be applied to design optimized operator routes. In one instance, the routing algorithm may determine the shortest possible route that visits every point in a set location one time. In one instance, system 200 may be tested over a three-month period using data simulation, with real feedback from the operations team used to fine-tune and improve the model’s accuracy. In other instances, the system 200 may be tested over a longer or shorter time period, such as, for example, a period of days, weeks, months, or years. Additionally, the system 200 may be validated based on the performance in key areas such as maximizing production and reducing operational costs.

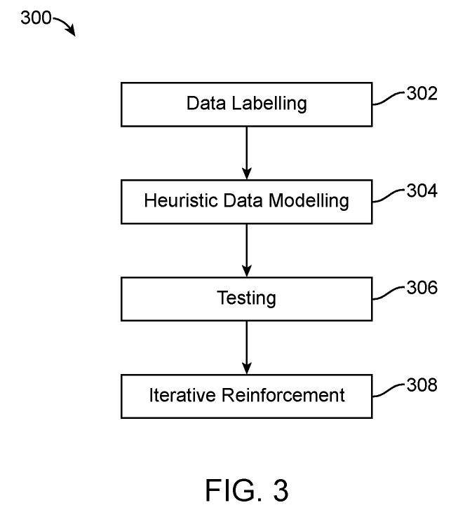

The validation highlights system 200 effectiveness in improving operator performance by maximizing production, optimizing travel routes, reducing costs, and enhancing field compliance. The optimized routing algorithm may significantly reduce travel time and GHG emissions, supporting sustainability goals. Integration with SCADA data may enable real-time visualization and predictive alarms, helping operators address issues before they escalate. Comparisons with conventional operational methods may show that the model provides a more efficient, cost-effective, and environmentally friendly approach. Continuous refinement of the model (as discussed later in FIGS. 3 and 4), driven by field feedback (as discussed later in FIGS. 3 and 4), may ensure that the model adapts to changing conditions, delivering sustained operational benefits.

In one instance, a benefit of the optimization model of system 200 may be to optimize daily operations. One way to optimize daily operations may be to create optimized action lists and routes for operators, ensuring they focus on high-impact tasks. In another instance, a benefit of the optimization model of system 200 may be to reduce operational costs. One way to reduce operational costs may be to minimize travel time and operational expenses through an optimized routing algorithm. In yet another instance, a benefit of the optimization model of system 200 may be to lower the environmental impact. One way to lower the environmental impact may be to reduce greenhouse gas emissions by minimizing unnecessary trips and optimizing routes. In yet another instance, a benefit of the optimization model of system 200 may be to enhance decision-making capabilities. One way to enhance decision making capabilities may be to reduce the cognitive load on operators by automating the planning process and highlighting urgent items. In another instance, a benefit of the optimization model of system 200 may be to predict and prevent issues. One way to predict and prevent issues may be to integrate SCADA data with advanced prediction algorithms to foresee and address potential issues in the field. In another instance, a benefit of the optimization model of system 200 may be to centralize operations management. One way to centralize operations management may be to provide a singular, accessible platform for all operational activities and SCADA data.

The development of the prioritization model 202 for operator optimization may involve several key phases, each integral to achieving the objectives of enhancing economic efficiency, optimized resource utilization, improved spatial efficiency, and support for environmental sustainability. These phases are shown and discussed further in FIG. 3 and may include, but are not limited to, data labeling, heuristic data modelling, rigorous testing and iterative reinforcement.

The operator optimization feature may generate an optimized route by prioritizing operational alarms and actions. The route may be determined based on the distances between locations. The distance between locations may be calculated using API endpoints. The distance calculation may ensure that operators can efficiently address the most critical tasks while minimizing travel time.

The operator optimization planner introduces several innovative features designed to enhance oilfield operations by optimizing daily tasks and reducing operational inefficiencies. In some instances, features being used to enhance oilfield operations may include, but are not limited to: action list creation, supervisory control and data acquisition (SCADA) integration and data visualization with predictive alarms, optimized routing algorithm, customized filters and flexibility, and minimization of cognitive load. The list of action items may allow users to create a detailed list of actions, alarms, and locations to address along an optimized route. The action list creation may ensure that operators focus on tasks with the greatest impact, minimizing time and effort while maximizing efficiency. Additionally, the action list creation may ensure that any action items flagged as “must do” have been included in the action list. Further, the action list creation may allow an operator an opportunity to evaluate and adjust the action item list as needed. As such, an operator may determine that an action item flagged as “must do” should be moved higher on the action item list in order to complete the flagged action item in a timely manner. For example, in an instance when a long action item list is generated but the item flagged as “must do” has been put lower on the action item list due a more efficient routing option and an operator knows the importance of completing that action item before others on the action item list.

The SCADA integration and data visualization with predictive alarms may integrate with a company’s SCADA system to collect and display various data points such as production levels, condensate-to-gas ratios, plunger rise and fall rates, and pipeline temperatures, to name but a few data. The SCADA integration and data visualization with predictive alarms may combine real-time SCADA data with the historical data points, the system may use advanced prediction algorithms to create alarms that can foresee issues such as drops in production or slow plungers before they occur.

In some instances, the optimized routing algorithm of the prioritization model 202 may consider various factors, but is not limited to, emptying tanks within the operator-specified timeframe, creating a schedule that optimizes delivery costs per liter over a selected period, the start and end locations, the distance limitations, the work duration limits, the travel time limits, a fuel type, the fuel consumption limits, the priority and urgency of tasks, the limits for the time to complete each task, the limits on the volume of material to be transferred, and other optional filters. The optimized routing algorithm may generate the most efficient route, reducing travel time, operational expenses, and greenhouse gas emissions.

In some instances, the customizable filters and flexibility may allow operators to empty tanks within the operator-specified timeframe, create a schedule that optimizes delivery costs per liter over a selected period, set start and end locations, set distance limitations, set work duration limits, set travel time limits, select a fuel type, set fuel consumption limits, set priority and urgency of tasks, set limits for the time to complete each task, set limits on the volume of material to be transferred, and other optional filters. The customizable filters and flexibility may allow operators to tailor the plan to their specific needs and constraints, improving overall operational effectiveness.

The minimization of cognitive load may reduce the cognitive burden on operators by automating the planning process and highlighting urgent items. The minimization of cognitive load enhances decision-making and planning efficiency, allowing operators to focus on execution rather than planning.

The operator optimization planner may embody new features that significantly enhance the efficiency, sustainability, and safety of oilfield operations. By automating and optimizing the planning process, integrating SCADA data, and providing clear and accessible information, the planner helps operators make better decisions, reduces operational expenses and greenhouse gas emissions, and ensures critical tasks are addressed promptly. The practical results obtained through the implementation of these features underscore their value, demonstrating substantial improvements in operational effectiveness and environmental impact.

Method 300 may include several key phases: data labelling at Step 302, heuristic data modeling at Step 304, testing at Step 306, and iterative reinforcement at Step 306, among others.

In Step 302 of method 300, the data may be prepared for optimization such as described above for data acquisition 102. The preparation may involve the implementation of a Fibonacci prioritization technique to assign priority scores to all field events, encompassing both scheduled and ad hoc occurrence. Further, the Fibonacci scores may be determined based on various parameters, which may include, but are not limited to, time, external factors such as weather and SCADA sensor data, and distance matrix analysis. The Fibonacci Score may be a range, for example, a range from Fibonacci(4) which is equal to 3 to Fibonacci(16) which is equal to 987. The structured approach of step 302 may ensure that the data is accurately labelled and ready for the next phase of optimization.

In Step 304 of method 300, the heuristic data modelling techniques may be deployed, such as those described above for heuristic methods 104, metaheuristic algorithms 106, and handling constraints 108. The data modelling techniques may include, but are not limited to, integrating practical, experience-based rule-of-thumb strategies with a routing algorithm. In one instance, the routing algorithm determines the shortest possible route that visits every point in a set location one time Additionally, the K-means clustering may be utilized to understand the distance dynamics between different well locations, factoring this into the heuristics to design an optimal route. Further, in one instance, a forecasting technique may be used. In one instance, for example, the forecasting technique may be used to study a well’s natural decline. Forecasting may help in designing an alarming system to indicate when a well experiences a dip in production. In another instance, the forecasting technique may be used to determine a regular maintenance schedule based on the failure rate of specific components. Additionally, the combination of these techniques in Step 204 may facilitate the generation of an optimized list or route, tailored to maximize operational impact for operators.

In Step 306 of method 300, the optimization model undergoes rigorous testing through a data simulator, spanning a defined period, which may be, for example, days, weeks, months, or years, although a sample of three months seems satisfactory. Additionally in Step 306, the optimization model may verify the model’s accuracy across key performance indicators (KPI’s), which may be, but is not limited to, maximized production, reduced operational costs, and low-risk field operations. Further, upon verification of the output, necessary adjustments may be made before deployment. The adjustments may ensure that the optimization model meets the desired performance standards.

In Step 308 of method 300, the optimization model may perform an iterative reinforcement as described above for the iterative process 110 and the reinforcement learning 112. In this step, the optimization model is deployed, the on-field operations team utilizes the generated list and provides feedback outcomes. The feedback loop may enable iterative refinement of the model’s hyperparameters, enhancing its efficiency over time. Each iteration may be saved to a memory. The memory may contain the date from individual iterations as well as historical data. The iterative process 110 retrieves the data from memory to refine the process and develop an optimal solution. In some instances, the iterative process 110 may retrieve data from individual iterations. In other instances, the iterative process may retrieve historical data. In some instance, for example, the iterative reinforcement in Step 308 performs a continuous improvement cycle. The continuous improvement cycle ensures that the optimization model remains adaptive and responsive to real-world operational conditions.

The method of deploying the optimization model may be a comprehensive process involving data labelling, heuristic data modelling, rigorous testing, and iterative reinforcement. Each phase may be meticulously designed to enhance the model’s effectiveness and efficiency. By leveraging advanced techniques such as the Fibonacci prioritization, K-means clustering, a forecasting technique used to, for example, study a well’s natural decline or to generate a maintenance schedule based on the failure rate of specific components, and determining the shortest possible route that visits every point in a set location one time, the optimization model of method 300 delivers optimized solutions that align with the operational objectives and efficiency standards.

FIG. 4 is a flow chart of method 400, which is a method of reviewing and optimizing alarms. Method 400 is used by the alarm indicator 208 in FIG. 2.

During Step 402 of method 400, the review step, which may be performed at a predefined time such as a morning or shift starts, the operators start by reviewing the alarms and field events generated by the system, which may include new alarms since the last review or uncleared items identified in earlier reviews. The alarms may be, but are not limited to, well production 222, weather-based alarm(s) 224, equipment alarms, and/or internally generated alarm(s) 226 as discussed in FIG. 2.

In Step 404 of method 400, during the managing alarms and events phase, the operators acknowledge and address alarms and field events, investigating causes and taking necessary actions like resetting, snoozing, and/or completing alarms that are already addressed. Managing alarms and events may offer customization and flexibility, as described above for customization and flexibility 114 as well as operator flexibility 118.

In Step 406 of method 400, when the daily data is entered, each operator may input, for example, a time to empty tanks within an operator-specified timeframe, a schedule that optimizes delivery costs per liter over a selected period, start and end locations, distance limitations, work duration limits, travel time limits, a fuel type, fuel consumption limits, priority and urgency of tasks, limits for the time to complete each task, limits on the volume of material to be transferred, and other optional filters, or other specific constraints into the operator optimization model. In another instance, other constraints may be used. Each operator may use an interactive display to input these specific constraints. The entry of specific constraints may be part of the data ingestion and model training 116. In one instance, for example, the constraints (as described above for handling constraints 108), may be a ‘vehicle Capacity’ constraint which checks if the demand is greater than the capacity of the truck. In one instance, for example, the constraints may be a ‘tank Not Ready’ constraint which determines if the demand for the thank is less than the rate, then there is no need to fill the tank. In one instance, for example, the constraints may be a ‘tank Empty’ constraint which never allows the tank to go empty. In one instance, for example, the constraints may be a ‘daysLeftTilEmpty’ constraint which should never be less than eight days, unless a tank is critical. In one instance, for example, the constraints may be a ‘methanolCost’ constraint which rewards higher product movement. In another instance, for example, an action item may be flagged as “must do” in order to ensure that action item may be given greater prioritization regardless of other constraints set.

In Step 408 of method 400, the system may automatically generate an optimized action item list and an optimized route. In Step 408, the system may perform similar methods and algorithms such as those described above for heuristic methods 104 and metaheuristic algorithms 106. In some instance, the optimized action item list and optimized route may be based on travel time, task priority, and urgency to name a few variables. In one instance, the optimized action item list and optimized route may be the shortest possible route that visits every point in a set location one time. In another instance, the optimized action item list and optimized route may be based on the priority and urgency of tasks. In one instance, for example, the optimized action item list and optimized route may list replace broken swadgelok T-fitting higher on the list, indicating that it must be done before, another action item, such as preventative maintenance. The action items may include, but are not limited to, gas and condensate samples, preventative maintenance, monthly carseal inspection, plunger inspection, ROW inspection, replace broken swadgelok T-fitting, tank inspection, production pig, receive pig, fuel refill, riser inspection, well site inspection, well samples, pull old soiled plunger and replace with spiral plunger, order more replacement components, etc.

In Step 410 of method 400, the optimized action list and optimized route automatically generated in Step 408 may be manually reviewed by an operator. The manual review process offers flexibility as described above for customization and flexibility 114 and operator flexibility 118. During the managing and editing the plan phase, the operators review, manage, and manually edit the generated optimized action list and optimized route, as needed. In one instance, for example, the operator may determine that the replacement components needed for a repair may not be available, yet. Thus, the repair or prescheduled maintenance action item may be moved to a lower position on the priority list to be completed at a later time. In another instance, for example, the operator may determine that an emergency repair may need to be completed before another action item on the list. Thus, the operator may move actions, such as the emergency repair, higher on the priority list to be completed before another action item.

In some instances, during the manual review by an operator, an operator may select items flagged as “must do” to ensure they are incorporated into the generated optimized action item list. Further, in other instances, an operator may be able to manually override the automatically generated optimized action item list an optimization route. An operator may move an action item flagged as “must do” higher on the generated optimized action list. In an instance, for example, an operator may determine that the generated optimized action item list is long and if the optimized action item list is followed in the order that it has been generated in, an action item flagged as “must do” is too low on the generated optimized action item list and will not be addressed in a timely manner. In another instance, for example, an operator may determine that an action item flagged as “must do” should be given greater prioritization regardless of other optimization constraints that were used to generate the optimized action item list. In such instances, a manual override allows an operator to manually incorporate the action item flagged as “must do” and/or adjust the generated optimized action item list and move an action item flagged as “must do” higher on the action item list in order to give the action item greater prioritization. This manual override overlays operator intuition with machine intelligence, which results in an optimized action item list that adapts better to the ever-changing field conditions.

In Step 412 of method 400, the operators follow the optimized action item list and route to execute the plan, with the system providing updates and adjustments as necessary.

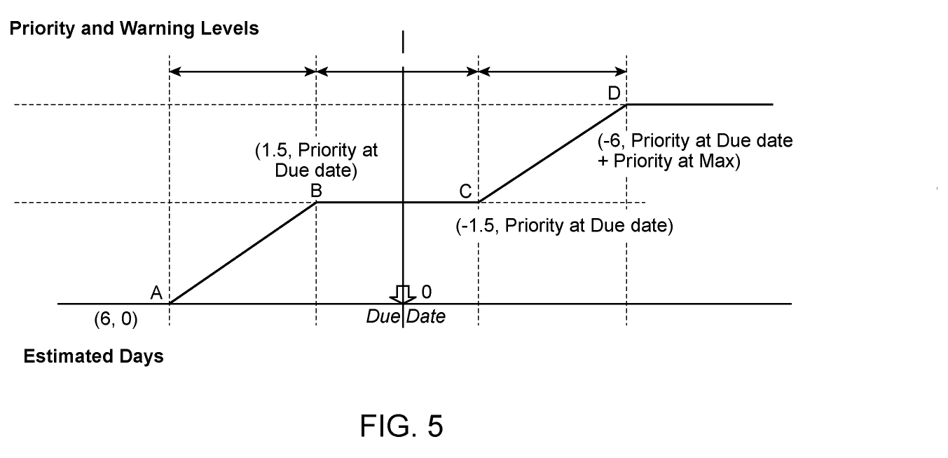

FIG. 5 illustrates a graph of priority and warning levels of each action item provided by the prioritization model of FIG. 2. FIG. 5 shows the priority and warning levels. The Estimated Days shown along the horizontal axis may be the difference between the reference date and activity due date. Each activity has an activity priority baseline which may be the bottom-most horizontal axis on the graph, a priority level of zero. The middle-horizontal axis of the graph may be the Priority at the Due Date, a Priority Level 1. The highest horizontal axis may be the max priority, a Priority Level 2. The graph may be further divided into vertical segments, which includes the warnings issued.

The distance between Point A to Point B on the graph is Priority AB. Priority AB is the gradient that trigger when Estimated Days are in between Warning A and Warning B. The distance between Point B and Point C on the graph is Priority BC. Priority BC is shown as the plateaued flat line before and after the due date based on the warning in-between window. The Priority BC trigger is when Estimated Days are in between Warning B and Warning C. Similarly, the distance between Point C and Point D is Priority CD. Priority CD is the gradient that assigned priority when the Estimated Days are in between Warning C and Warning D. Priority CD will be kept at the max Priority Level after Warning D. An activity at the Priority Baseline, which is a priority level of zero, a warning is issued before the due date. At Priority Level 1, a warning is issued between the estimated reference date and the activity due date. At Priority Level 2, a warning is issued after the due date. After reaching Priority Level 2, the warning level remains the same. The Overall Priority Level is categorized as a compilation of Priority Level 1 + Priority Level 2 + Priority AB + Priority BC + Priority CD.

The graph in FIG. 5 shows Point A at coordinates (6,0) which indicates there are 6 estimated days between the reference date and the activity due date at the priority baseline with a priority level of 0. A warning may be issued before the due date of Point A. Point B is on the graph at coordinates (1.5, priority due date) which indicates Point B has 1.5 estimated days between the reference date and the activity due date and is elevated to Priority Level 1 at the priority due date. Point C on the graph is at coordinates (-1.5, priority due date), which indicates the action is 1.5 days past due from the reference date and the activity due date and is at Priority Level 1 at the priority due date. A warning may be issued in between Point B and Point C as the due date is reached. Point D on the graph is at coordinates (-6, priority due date + max priority), which indicates the activity is 6 days past due from the estimated days between the reference date and the activity due date and is now elevated to a Max Priority position which is Priority Level 2, in this example. A past due warning may be issued at Point D. The warning level at Point C will remain the same until the action item is completed.

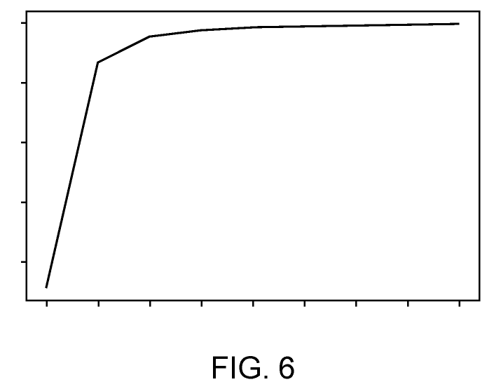

FIG. 6 illustrates a graph of a heuristic data modeling as discussed in FIG. 3, Step 304. K-means clustering may be used to understand the distance dynamics between different well locations to determine an optimal route between action items. FIG. 6 shows the score along the y-axis, which is a range from -4 to 0 from bottom to top. The number of clusters is displayed along the x-axis, which is a range from 1 to 9. FIG. 6 is an elbow shaped graph which represents the score per the number of clusters. The graph shows that as the number of clusters increases from 1 to 9, the score increases and levels out at 0.

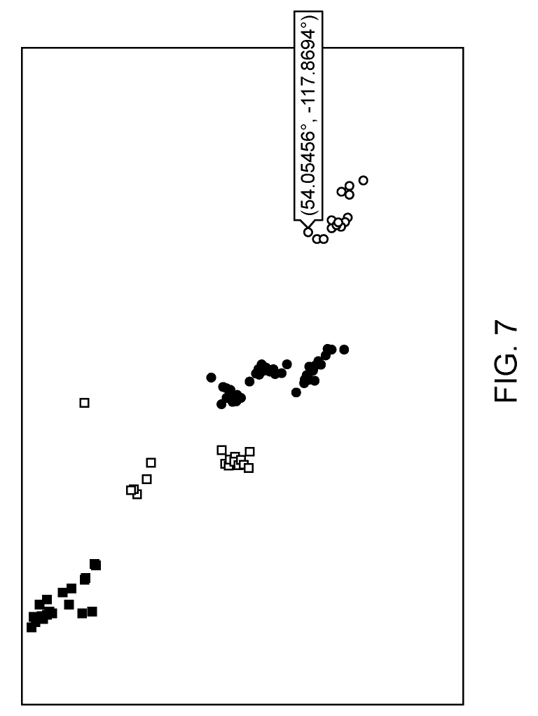

FIG. 7 illustrates a graph of the clusters of data used for heuristic data modelling of FIG. 3. The clusters on the graph represent the distance between the action items. The cluster of dots near the top left of the graph represents action items that are all close in distance to one another. While the cluster of dots near the lower right portion of the graph represents other action item that are close in distance to one another. The representation of clustered data in FIG. 7 is used in the heuristic data modeling of Step 306 of FIG. 3.

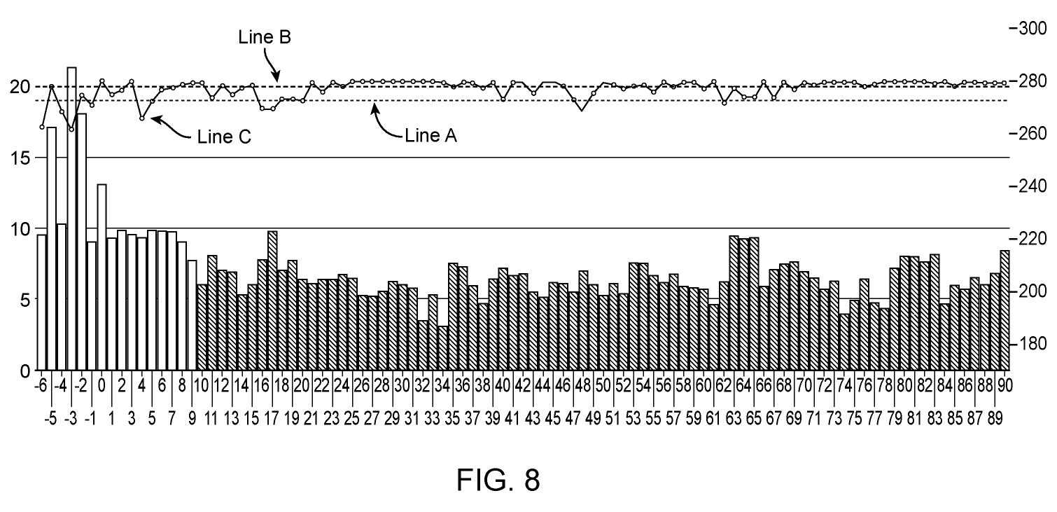

FIG. 8 illustrates a graph of the maximized production showing the number of hours in the field over a period of days. In the graph of FIG. 8, the y-axis represents the number of hours in the field, which is a range of 0 hours to 20 hours. The x-axis represents the day in the field, which is a range starting at -6 days through 90 days. The individual bars represent the number of hours in the field per day. In one instance, for example, on day 10, just over 5 hours were spent in the field. In another instance, for example, on day 65, about 9 hours were spent in the field. As shown in the graph, between day -6 and day 9, the number of hours is substantially higher, which varies from around 9 hours to above 20 hours per day, than the average number of hours between day 10 and day 90, which remains well under 10 hours per day.

Line A, Line B, and Line C represents the sum of the production volume (E3M3). Line A represents the average production before the implementation of the optimization model. The average production of Line A is an average of 272.3. Line B represents the average production after optimization. Line B shows an average of 277.4. Thus, the average production volume increased from 272.3 to 277.4 from before the optimization model of system 200 was implemented. Line C represents the production by volume per day. As shown, Line C varies widely from day -6 to day 9. On Day 10, the optimization model was implemented and tested, the production by volume per day remained near 280 from day 10 through day 90.

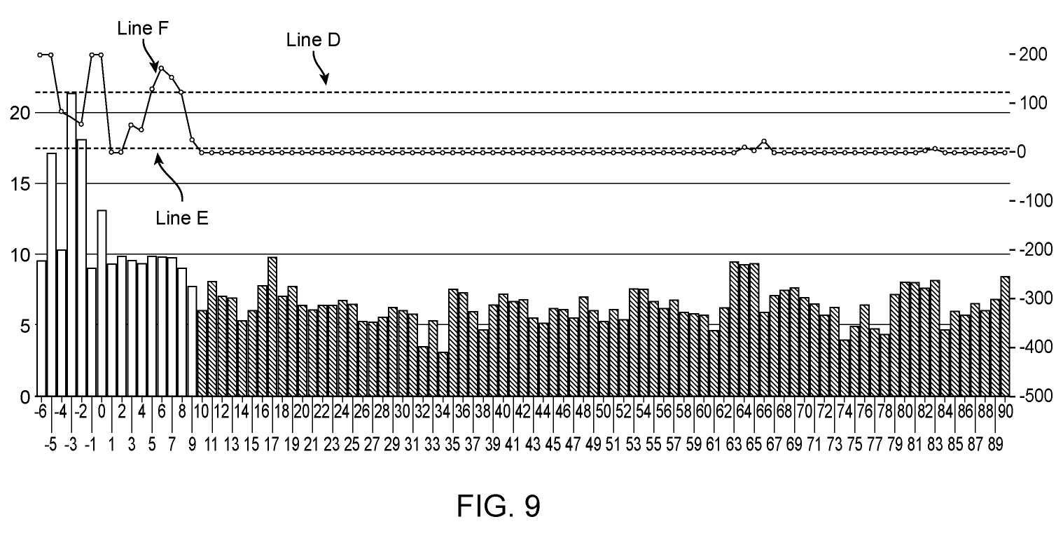

FIG. 9 illustrates a graph of the optimization of the lower OPEX and cost. In the graph of FIG. 9, the y-axis represents the number of hours in the field, which is a range of 0 hours to 20 hours. The x-axis represents the day in the field, which is a range starting at -6 days through 90 days. The individual bars represents the number of hours in the field per day. In one instance, for example, on day 10, just over 5 hours were spent in the field. In another instance, for example, on day 65, about 9 hours were spent in the field. As shown in the graph, between day -6 and day 9, the number of hours is substantially higher, which varies from around 9 hours to above 20 hours per day, than the average number of hours between day 10 and day 90, which remains well under 10 hours per day.

Line D, Line E and Line F represents the sum of the excess methanol measured in Liters. Line D represents the average over-injection in liters before the optimization model was implemented. The average over-injection is 123 Liters, shown by Line D. Line E represents the average over-injection in liters after the optimization model was implemented. The average over-injection is 8 Liters, as shown by Line E. Thus, the average over-injection rate decreased from 123 Liters to 8 Liters, decreasing by 115 Liters, on average, after the optimization model was implemented. Line F represents the trend for excess methanol pumped in Liters. The excess methanol pumped varies widely between days -6 through day 9. On day 10, when the optimization model was implemented, the excess methanol level pumped levels off near 0 Liters and stays substantially flat through day 90.

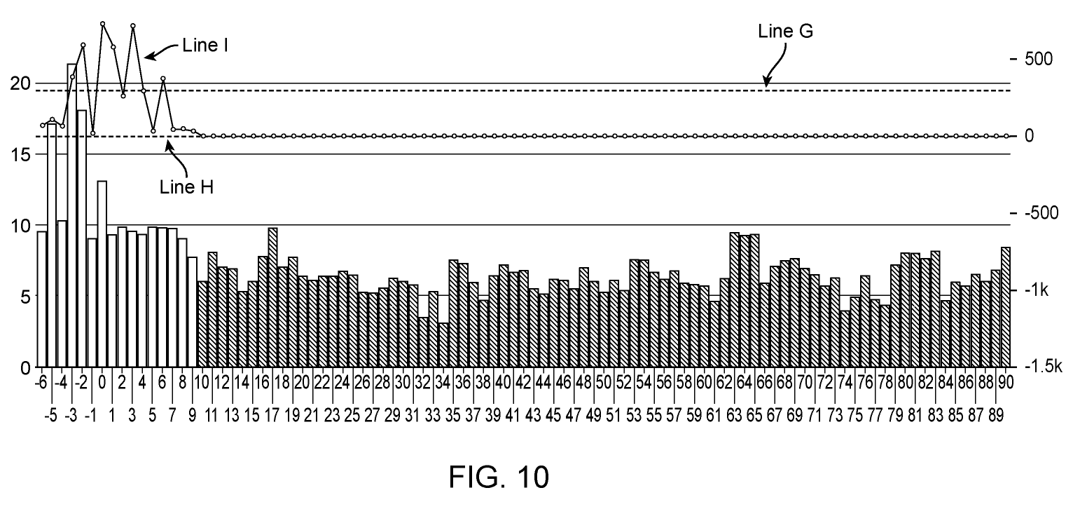

FIG. 10 illustrates a graph of the compliant/low risk operations. In the graph of FIG. 10, the y-axis represents the number of hours in the field, which is a range of 0 hours to 20 hours. The x-axis represents the day in the field, which is a range starting at -6 days through 90 days. The individual bars represents the number of hours in the field per day. In one instance, for example, on day 10, just over 5 hours were spent in the field. In another instance, for example, on day 65, about 9 hours were spent in the field. As shown in the graph, between day -6 and day 9, the number of hours is substantially higher, which varies from around 9 hours to above 20 hours per day, than the average number of hours between day 10 and day 90, which remains well under 10 hours per day.

Line G, Line H and Line I represents the sum of the days delinquent of the compliant and low risk operations. Line G represents the average number of days delinquent before the optimization model was implemented. The average number of days delinquent is 294 days, shown by Line G. Line H represents the average number of days delinquent after the optimization model was implemented. The average number of days delinquent is 0, as shown by Line H. Thus, the average number of days delinquent decreased from 294 days to 0 days, decreasing by 294 days, on average, after the optimization model was implemented. Line I represents the trend for number of days delinquent for the compliant and low risk operations. The number of days delinquent varies widely between day -6 through day 9, and bounces between near 0 days and over 500 days. On day 10, when the optimization model was implemented, the number of days delinquent levels off near 0 days and stays at 0 days through day 90.

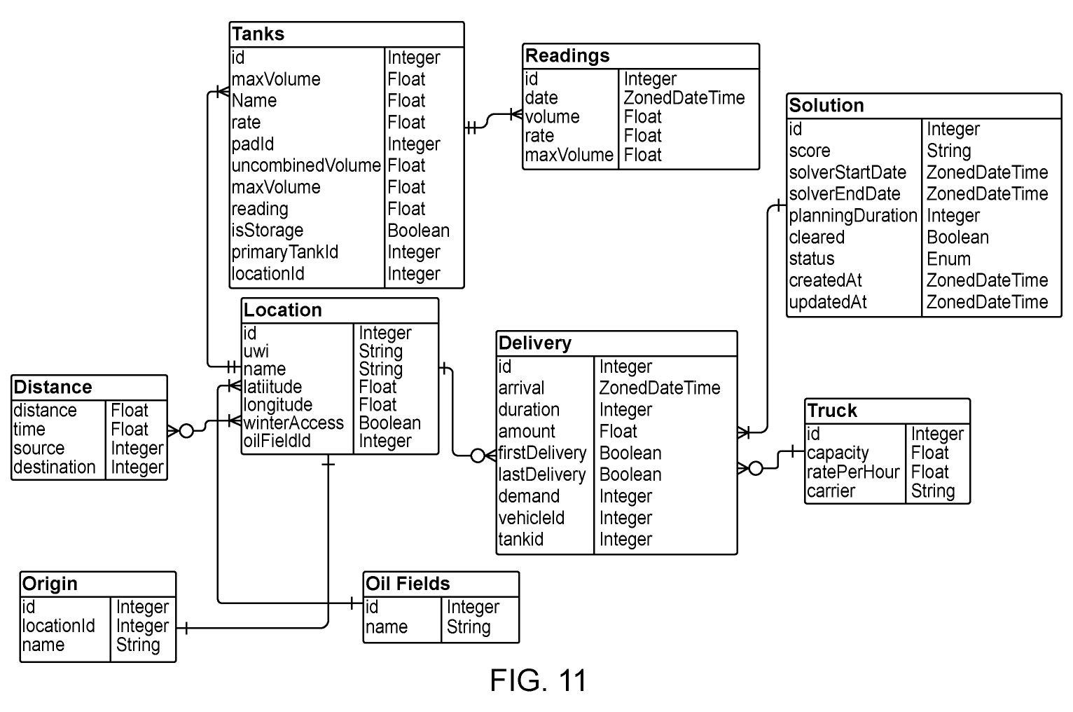

FIG. 11 illustrates an example of the architecture that is used to determine priority of action items by the prioritization model 202 of FIG. 2 for optimization. The prioritization model 202 may generate a priority list 210 of action items that need to be completed with a priority level attached. In one instance, the priority list 210 may be generated based on at least one of an origin, a distance, a location, a tank, an oil field, a delivery, a reading, a solution, and a truck as shown in FIG. 11. In another instance, the priority list 210 may be generated based on an operator’s manually prioritized task list due to, for example, availability of replacement parts.

In other instances, other configurations are possible. For example, those of skill in the art will recognize, according to the principles and concepts disclosed herein, that various combinations, sub-combinations, and substitutions of the components discussed above can provide appropriate control for a variety of different configurations of robotic platforms for a variety of applications.

The previous description of the disclosed embodiments is provided to enable any person skilled in the art to make or use the invention. Various modifications to these embodiments will be readily apparent to those skilled in the art, and the generic principles defined herein may be applied to other embodiments without departing from the spirit or scope of the invention. Thus, the invention is not intended to be limited to the embodiments shown herein but is to be accorded the widest scope consistent with the principles and novel features disclosed herein.

1. A system of optimizing, the system comprising:
a prioritization model, the prioritization model comprising:
a time delta function, the time delta function generating a Fibonacci score for each of a plurality of action items;
a distance optimizer, the distance optimizer determining a best score for each of the plurality of action items, the best score based on a distance to travel;
an alarm indicator, the alarm indicator generates an alarm indicator input for the prioritization model;
wherein the prioritization model generates a prioritized list of the plurality of action items based on the Fibonacci score, the best score, and the alarm indicator input.

2. The system of claim 1, wherein the time delta function uses a pigging event, an inspection schedule and a machine schedule, a task, and a non-scheduled event to determine the Fibonacci score.

3. The system of claim 2, wherein the pigging event is based on a pigging frequency and a number of days the pigging event is overdue.

4. The system of claim 2, wherein the inspection schedule and the machine schedule are based on a pigging frequency and a number of days the pigging event is overdue.

5. The system of claim 2, wherein the task is based on a difference between a current date and a creation date.

6. The system of claim 2, wherein the non-scheduled event includes a tank reading or a pump reading.

7. The system of claim 1, wherein the Fibonacci score is determined by a priority level of each of the plurality of action items.

8. The system of claim 1, wherein the alarm indicator input is based on at least one of a well production alarm, a weather-based alarm, and an internally generated alarm.

9. The system of claim 8, wherein the well production alarm is a percentage of decrease commodity pricing and percentage of ownership.

10. The system of claim 8, wherein the weather-based alarm is either one of an under-injection or an over-injection based on a recommended rate.

11. The system of claim 8, wherein the internally generated alarm is either one of a visitation alarm or a pig receiver full alarm.

12. A method of optimizing, the method comprising:
having a prioritization model, the prioritization model comprising:
an alarm indicator, the alarm indicator generates an alarm indicator input for the prioritization model;
receiving data and labelling the received data with a Fibonacci score for each of a plurality of action items, the Fibonacci score is generated by a time delta function;
using a heuristic data model to determine a best score for each of the plurality of action items, the best score based on a distance to travel; and
testing the prioritization model for a duration of time;
performing a continuous improvement cycle to reinforce an efficiency of the prioritization model; and
generating a prioritized list of the plurality of action items based on the Fibonacci score, the best score, and the alarm indicator input.

13. The method of claim 11, wherein the time delta function uses a pigging event, an inspection schedule and a machine schedule, a task, and a non-scheduled event to determine the Fibonacci score.

14. The method of claim 12, wherein the pigging event is based on a pigging frequency and a number of days the pigging event is overdue.

15. The method of claim 12, wherein the inspection schedule and the machine schedule are based on a pigging frequency and a number of days the pigging event is overdue.

16. The method of claim 12, wherein the task is based on a difference between a current date and a creation date.

17. The method of claim 12, wherein the non-scheduled event includes a tank reading or a pump reading.

18. The method of claim 11, wherein the Fibonacci score is determined by a priority level of each of the plurality of action items.

19. The method of claim 11, wherein the alarm indicator input is based on at least one of a well production alarm, a weather-based alarm, and an internally generated alarm.

20. The method of claim 11, wherein the duration of time is 90 days.
